(19) United States
(12) Patent Application Publication
(10) Pub. No.: US 2015/0358605 A1
(43) Pub. Date: Dec. 10, 2015

(54) STEREO CAMERA MODULE AND METHOD FOR THE PRODUCTION THEREOF

(71) Applicant: CONTI TEMIC MICROELECTRONIC GMBH, Nürnberg (DE)

(72) Inventors: Gerhard Müller, Bad Waldsee (DE); Sven Kujat, Oberstaufen (DE); Marko Alexovski, Bermatingen (DE)

(73) Assignee: Conti Temic Microelectronic GmbH, Nurnberg (DE)

(21) Appl. No.: 14/759,551

(22) PCT Filed: Dec. 12, 2013
(86) PCT No.: PCT/DE2013/200361

§ 371 Date: Jul. 7, 2015

(30) Foreign Application Priority Data
Mar. 19, 2013 (DE) 10 2013 102 820.9

(51) Int. Cl. H04N 13/02; H05K 3/30; H05K 3/32; H04N 5/225

(52) U.S. Cl. CPC H04N 13/0239; H04N 5/2252; H05K 3/301; H05K 3/32

(57) ABSTRACT

A stereo camera module, which includes a first image sensor and a second image sensor, a support having mounting surfaces aligned substantially in the same plane and for arrangement of the first and second image sensors on these mounting surfaces, a first lens housing arranged on the support and having an optical system for the first image sensor, a second lens housing arranged on the support and having an optical system for the second image sensor, and a printed circuit board arrangement for electrically contacting the first and the second image sensors through the support. The first and second image sensors are each in the form of an image sensor chip having wire bond connections and the printed circuit board arrangement has wire bond surfaces for contacting the wire bond connections of the first and second image sensor chips.

### CROSS REFERENCE TO RELATED APPLICATIONS

This application is the U.S. National Phase Application of PCT/DE2013/200361, filed Dec. 12, 2013, which claims priority to German Patent Application No. 10 2013 102 820.9, filed Mar. 19, 2013, the contents of such applications being incorporated by reference herein.

### FIELD OF THE INVENTION

The invention relates to a stereo camera module and a method for the production of the stereo camera module.

### BACKGROUND OF THE INVENTION

Such stereo camera modules are used in vehicles to record the surroundings of the vehicle, in order to be able to use the image data for a wide variety of functions such as e.g. for lane detection, traffic sign recognition, high-beam assist, collision warning, pedestrian detection, etc., wherein interventions in vehicle control systems, e.g. brake or engine control systems, are also made based on the evaluated image data. These stereo camera modules are able to create a three-dimensional construction of the surroundings, based on the offset between pixels of two captured images.

In order to achieve a high quality of such a stereo camera module, it is necessary for the two camera modules of such a stereo camera module to be aligned towards each other, in particular with regard to the roll angle (twisting about the optical axis). Ideally, the image lines of both camera modules of the stereo camera module are aligned parallel to each other and do not have any lateral offset.

A stereo camera module is known from EP 1 816 514 B1, incorporated by reference herein which comprises a rectangular support which is configured with a flange projecting vertically to the support at each end, said flange having a reference surface as a mounting surface for a housed image sensor. Each of the two image sensors arranged on this reference surface is contacted through the reference surface with a printed circuit board connected to the support behind the flange. The two reference surfaces for the two image sensors are substantially configured in the same plane or substantially in parallel planes on the support. A plurality of reference planes are provided for positioning on the housing of the image sensors, wherein the support additionally comprises at least one positioning surface in a position opposite the reference plane, so that the housed image sensors are, in each case, pressed against the mounting surface and the positioning surface by a retaining plate and are connected to the mounting surface by means of an adhesive connection. Finally, the support of this known stereo camera module can also include marks or structures, which can serve as reference for positioning the housed image sensors on the mounting surfaces, and which can be detected by a video camera.

In the case of this known stereo camera module a roll angle adjustment is probably achieved between the support and the housed image sensor, however the roll angle tolerances remain inside the housed image sensor, i.e. between the image sensor chip and the image sensor housing. These tolerances are not compensated for either by the fact that, if reference planes are present on the surface of the image sensor housing, they are aligned to associated positioning surfaces of the support. As a rule, these tolerances inside the housed image sensor exceed the permissible total tolerance of the stereo camera module. In addition, it is also disadvantageous in the case of this known stereo camera module that each of the two image sensors is aligned to a positioning surface of the support. This is because this requires a low tolerance of the positioning surfaces assigned to the two image sensors with regard to the alignment thereof.

### SUMMARY OF THE INVENTION

An aspect of the invention is to create a stereo camera module of the aforementioned type, with which an improved roll angle adjustment is achieved compared with the prior art and which, nevertheless, has a structurally simple construction. A further aspect is a method for the production of such a camera module.

Such a stereo camera module which comprises a first image sensor and a second image sensor, a support having mounting surfaces aligned substantially in the same plane and for arrangement of said first and second image sensors on these mounting surfaces, a first lens housing arranged on the support and having an optical system for the first image sensor, a second lens housing arranged on the support and having an optical system for the second image sensor, and a printed circuit board arrangement for electrically contacting the first and the second image sensors, is characterized according to the invention in that the first and second image sensors are each in the form of an image sensor chip having wire bond connections and the printed circuit board arrangement has wire bond surfaces for contacting the wire bond connections of the first and second image sensor chips.

As a result of the fact that only image sensor chips are used instead of housed image sensors, the tolerance chain between the two image sensor chips is significantly decreased. This tolerance chain only contains twice the roll angle tolerance between an image sensor chip and the support. Therefore, mechanical reference surfaces, which are provided according to the prior art in accordance with EP 186 514 B1, are not required. The two image sensor chips are actively positioned relative to features of the support.

According to an advantageous embodiment of the invention, the support is in the form of a plate and is preferably made of metal, wherein the mounting surfaces are provided on a first surface side of the support. A constructively simpler design of the stereo camera module according to the invention can therefore be achieved. It is preferably simply the case that the printed circuit board arrangement is arranged on a second surface side opposite the first surface side. A good thermal connection of the image sensor chips can be achieved thanks to the use of a metal plate as a support. If, in addition, a lens housing made of metal is used and the lens housing is connected to the metallic support by means of an adhesive connection, the selection of adhesive is simplified because of the similar materials to be connected. The tolerance chain between an image sensor chip and the associated lens housing is minimized as a result.

According to a further advantageous embodiment of the invention, the printed circuit board arrangement is configured in two pieces with a first printed circuit board for contacting the first image sensor chip and a second printed circuit board for contacting the second image sensor chip. If such printed circuit boards have a flexible design, the support can be simply connected to a main printed circuit board of the stereo camera module.

In an alternative embodiment of the invention, the printed circuit board arrangement is configured as a one-piece printed circuit board for contacting the first image sensor chip and the second image sensor chip. Such a one-piece printed circuit board can also have a flexible design, resulting in the connection to a main printed circuit board being reduced to a single connector. When a joint printed circuit board is used for both image sensor chips, the larger area means that components for the signal processing can also be arranged on this printed circuit board, as a result of which the main printed circuit board can be smaller and the total size of the stereo camera module according to the invention is therefore ultimately reduced.

According to a further advantageous embodiment of the invention, the first and second lens housings are each connected to the support by means of an adhesive connection. The optical system of each of the two lens housings can be aligned with respect to the associated image sensor chip, as a result of which a stereo camera module with minimum tolerances regarding the roll angle tolerances is provided, all in all.

In addition, in accordance with a further development, the support has openings in the area of the mounting surfaces for guiding through the wire bond connections of the two image sensor chips to the printed circuit board arrangement.

A method for the production of a stereo camera module is characterized by at least the following method steps:
Positioning and parallel alignment with minimum lateral offset of the first and second image sensor chips on the support,
Fixing of the aligned image sensor chips by means of a fixing means,
Contacting of the wire bond connections with the wire bond surfaces of the printed circuit board arrangement,
Configuration in each case of a first and second lens housing having an optical system for the first and second image sensor chips, and
Non-positive or positive connection of the first and second lens housings with the support.

In the case of this method for the production of the stereo camera module according to the invention, no mechanical reference surfaces according to the prior art in accordance with EP 1 816 514 B1 are required. Rather, the unhoused image sensor chips are actively positioned relative to features of the support on the same.

Outer edges of the support or openings in the support can preferably be used in order to actively position the image sensor chips.

### BRIEF DESCRIPTION OF THE DRAWINGS

It can also be advantageous to use stop edges of the support to align the image sensor chips.

The invention will be explained below in more detail with reference to the attached figures, where:

FIG. 1 shows a perspective exploded view of a stereo camera module according to the invention as an embodiment example, and

FIG. 2 shows a perspective sectional view of one of the two camera modules of the stereo camera module according to FIG. 1.

### DETAILED DESCRIPTION OF THE PREFERRED EMBODIMENTS

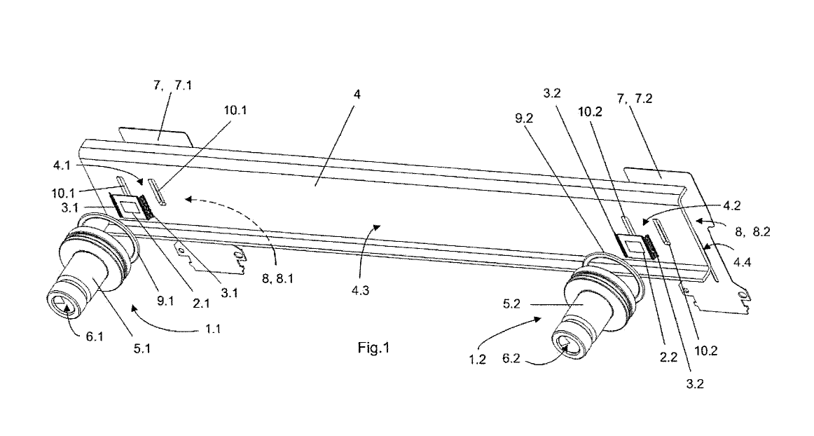

The stereo camera module 1 according to FIG. 1 for a vehicle assistance system of a vehicle includes a support 4, on which are arranged a first image sensor chip 2.1 and a second image sensor chip 2.2 as “bare dies” as well as, in each case, lens housings 5.1 and 5.2 assigned to these first and second image sensor chips 2.1 and 2.2, wherein the two lens housings 5.1 and 5.2 each have an optical system 6.1 and 6.2.

The support 4 is configured as a rectangular support plate, which is made of metal and extends in an x direction, the edges of which extend in a longitudinal direction (x direction) and are angled, so that a Z-shaped cross-section is created. Camera modules 1.1 and 1.2 of the stereo camera module 1 are, in each case, arranged at the ends of this support plate 4, said camera modules being formed by the first image sensor chip 2.1 with the associated lens housing 5.1 and the second image chip 5.2 with the associated lens housing 5.2.

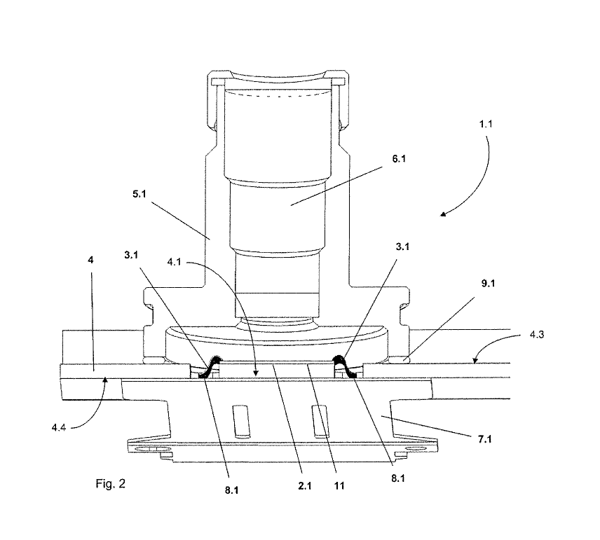

The first image sensor chip 2.1 is arranged by means of an adhesive connection (designated with the reference numeral 11 in FIG. 2) on a mounting surface 4.1 of the support plate 4 and the second image sensor chip 2.2 is arranged by means of a further adhesive connection on a further mounting surface 4.2 of the support plate 4, wherein these mounting surfaces 4.1 and 4.2 are located on a first, front surface side 4.3 of the support plate 4. As the support plate 4 is produced from metal, this results in a good thermal connection of the two image sensor chips 2.1 and 2.2 to the support plate 4, because the chips (“bare dies”) rest directly on the metallic surface of the support plate 4.

A printed circuit board arrangement 7 connected to the support plate 4, which has wire bond surfaces 8 for electrically contacting the two image sensor chips 2.1 and 2.2, is located on the second surface side 4.4, i.e. the rear side of the support plate 4.

To this end, the wire bond connections 3.1 and 3.2 respectively of the first and second image sensor chips 2.1 and 2.2 respectively are guided through openings 10.1 and 10.2 respectively arranged in the area of these mounting surfaces 4.1 and 4.2 to the rear side 4.4 of the support plate 4 to the printed circuit board arrangement 7 and are contacted there with the wire bond surfaces 8 of the printed circuit board arrangement 7.

According to FIG. 1, the printed circuit board arrangement 7 is composed of two individual flexible printed circuit boards 7.1 and 7.2, which each comprise wire bond surfaces 8.1 and 8.2 for contacting the wire bond connections 3.1 and 3.2 of the image sensor chips 2.1 and 2.2 guided through the openings 10.1 and 10.2 in the area of the mounting surfaces 4.1 and 4.2 of the support plate 4, as shown in the sectional view according to FIG. 2 for the image sensor chip 2.1 of the camera module 1.1, which is connected to the support plate 4 by means of an adhesive connection 11. The two flexible printed circuit boards 7.1 and 7.2 can additionally have a contact zone for the connection with a zero-force plug.

Instead of the flexible printed circuit boards 7.1 and 7.2, rigid printed circuit boards made of a FR4 material, which have a flexible area with a contact zone, can also be used.

As an alternative to the flexible area of such printed circuit boards 7.1 and 7.2, a plug-in connector can be used.

If the printed circuit board arrangement 7 is only composed of a single flexible printed circuit board (not shown in the figures) or, alternatively, of a single rigid printed circuit board made of a FR4 material, only a single connection to a main printed circuit board of the stereo camera module 1 is required. In those cases where a joint printed circuit board is used for both image sensor chips 2.1 and 2.2, the larger area means that components for the signal processing can also be arranged on this joint printed circuit board, so that these no longer have to be arranged on the main printed circuit board and, therefore, this main printed circuit board can be smaller in size. Since, as a rule, the main printed circuit board, together with the support plate 4 and the joint printed circuit board for the two image sensor chips 2.1 and 2.2, are located in a joint camera housing, this results in a reduction in the total size of a stereo camera constructed with the stereo camera module 1 according to the invention.

In addition, a flexible joint printed circuit board for the two image sensor chips 2.1 and 2.2 can also have a contact zone for the connection with a zero-force plug. In the case of an alternative use of a rigid joint printed circuit board for the two image sensor chips 2.1 and 2.2 made of a FR4 material, this has a flexible area with a contact zone; instead of the flexible area a plug-in connector can also be used.

The lens housing 5.1 of the first image sensor chip 2.1 and the lens housing 5.2 of the second image sensor chip 2.2 are connected to the first surface side 4.3 of the support plate 4 by means of adhesive connections 9.1 and 9.2 respectively, wherein the focus is first adjusted, before hardening of the adhesive for fixing the lens housings 5.1 and 5.2 respectively on the support plate 4. The tolerance chain between the image sensor chips 2.1 and 2.2 is therefore minimized, resulting in a low roll angle tolerance of the two image sensor chips 2.1 and 2.2 respectively with respect to the support plate 4. If the two lens housings 5.1 and 5.2 are made of metal, the bonding is effected by means of the adhesive connection 11 between similar materials, simplifying the selection of adhesive.

In order to produce a stereo camera module 1 in accordance with FIGS. 1 and 2, the following method steps are carried out:

The two image sensor chips 2.1 and 2.2 are first positioned on the support plate 4, and aligned parallel to each other with minimum lateral offset. These two image sensor chips 2.1 and 2.2 are actively positioned relative to features of the support plate 4.

The roll angle adjustment of the two image sensor chips 2.1 and 2.2 can therefore be guaranteed by means of a corresponding operating system for positioning the chips (dies). To this end, the support plate 4 is fixed in a receptacle of this operating system and it is thereby guaranteed by the same that the two image sensor chips 2.1 and 2.2 are adhesively bonded with the same roll angle adjustment. If necessary, the bracket for the support plate 4 in this operating system can be designed such that it only allows a displacement of the support plate in a longitudinal direction. The position for affixing the two image sensor chips 2.1 and 2.2 relative to the operating system would always remain in the same place, i.e. only the support plate 4 would be displaced.

An adhesive is used as a fixing means for the two image sensor chips 2.1 and 2.2, said adhesive hardening following the positioning and alignment of the two image sensor chips 2.1 and 2.2.

A contacting of the wire bond connections 3.1 and 3.2 of the two image sensor chips 2.1 and 2.2 is then effected with the wire bond surfaces 8 of the joint printed circuit board 7 or the wire bond surfaces 8.1 and 8.2 of the two printed circuit boards 7.1 and 7.2.

The finished lens housings 5.1 and 5.2 each having an optical system 6.1 and 6.2 for the first and second image sensor chips 2.1 and 2.2 are connected by means of an adhesive to the support plate 4 according to FIG. 2, fixed and the focus adjusted, and then hardened, in order to produce an adhesive connection 9.1 and 9.2 respectively with the support plate 4.

A stereo camera module 1 produced in this way only has a short tolerance chain between the two image sensor chips 2.1 and 2.2, which only has the two roll angle tolerances of the image sensor chip 2.1 and the image sensor chip 2.2 relative to the support plate 4, for example to one edge of the same.

In order to align the image sensor chips 2.1 and 2.2 on the support plate, a stop edge arranged on the support plate 4 can alternatively be provided in each case. It would also be possible to introduce an elastic element, in each case, for the two image sensor chips 2.1 and 2.2 into the support plate 4, said elastic element pressing each of the two image sensor chips 2.1 and 2.2 against such a stop edge.

Instead of such a stop edge integrated into the support plate 4, an auxiliary device can also be used with reference features, which mechanically positions the positioning of the two image sensor chips 2.1 and 2.2 relative to these reference features on the support plate 4. Such an auxiliary device can likewise have elastic elements, which press the two image sensor chips 2.1 and 2.2 and the support plate 4 against the reference features on the auxiliary device.

Finally, other positioning methods, which use optical measurement and corresponding micropositioning for example, can be used.

### REFERENCE NUMERALS

1 Stereo camera module

1.1 Camera module of the stereo camera module 1

1.2 Camera module of the stereo camera module 1

2.1 First image sensor chip

2.2 Second image sensor chip

3.1 Wire bond connections of the first image sensor chip 2.1

3.2 Wire bond connections of the second image sensor chip 2.2

4 Support

4.1 Mounting surface of the first image sensor chip 2.1

4.2 Mounting surface of the second image sensor chip 2.2

4.3 First surface side of the support 4, front side

4.4 Second surface side of the support 4, rear side

5.1 Lens housing of the first image sensor chip 2.1

5.2 Lens housing of the second image sensor chip 2.2

6.1 Optical system of the lens housing 5.1

6.2 Optical system of the lens housing 5.2

7 Printed circuit board arrangement

7.1 Printed circuit board of the first image sensor chip 2.1

7.2 Printed circuit board of the second image sensor chip 2.2

8 Wire bond surfaces of the printed circuit board arrangement 7

8.1 Wire bond surfaces of the printed circuit board 7.1

8.2 Wire bond surfaces of the printed circuit board 7.2

9.1 Adhesive connection

9.2 Adhesive connection

10.1 Openings for wire bond connections 3.1

10.2 Openings for wire bond connections 3.2

11 Adhesive connection of the image sensor chips 2.1 and 2.2

1. A stereo camera module, comprising
a first image sensor and a second image sensor,
a support having mounting surfaces aligned substantially in the same plane and for arrangement of said first and second image sensors on the respective mounting surfaces,
a first lens housing arranged on the support and having an optical system for the first image sensor,
a second lens housing arranged on the support and having an optical system for the second image sensor, and
a printed circuit board arrangement for electrically contacting the first and the second image sensors,
wherein
the first and second image sensors are each in the form of an image sensor chip having wire bond connections, and
the printed circuit board arrangement has wire bond surfaces for contacting the wire bond connections of the first and second image sensor chips.

2. The stereo camera module according to claim 1, wherein characterized in that the support is in the form of a plate and preferably made of metal, and the mounting surfaces are provided on a first surface side of the support.

3. The stereo camera module according to claim 2, wherein the printed circuit board arrangement is arranged on a second surface side opposite the first surface side.

4. The stereo camera module according to claim 1, wherein the printed circuit board arrangement is configured in two pieces with a first printed circuit board for contacting the first image sensor chip and a second printed circuit board for contacting the second image sensor chip.

5. The stereo camera module according to claim 1, wherein the printed circuit board arrangement is configured as a one-piece printed circuit board for contacting the first image sensor chip and the second image sensor chip.

6. The stereo camera module according to claim 1, wherein the first and second lens housings are each connected by an adhesive connection to the support.

7. The stereo camera module according to claim 1, wherein the support has openings in the area of the mounting surfaces for guiding through the wire bond connections of the two image sensor chips onto the printed circuit board arrangement.

8. A method for the production of a stereo camera module according to claim 1 the method comprising:
Positioning and parallel alignment with minimum lateral offset of the first and second image sensor chips on the support,
Fixing of the aligned image sensor chips by a fixing means,
Contacting of the wire bond connections with the wire bond surfaces of the printed circuit board arrangement,
Configuration in each case of a first and second lens housing having an optical system for the first and second image sensor chips, and
Positive or non-positive connection of the first and second lens housings to the support.

9. The method according to claim 8, wherein outer edges of the support or openings are used in order to align the image sensor chips.

10. The method according to claim 8, wherein stop edges of the support are used in order to align the image sensor chips.
